(19) United States
(12) Patent Application Publication
(10) Pub. No.: US 2026/0096117 A1
(43) Pub. Date: Apr. 2, 2026

(54) SEMICONDUCTOR DEVICE

(71) Applicant: Mitsubishi Electric Corporation, Tokyo (JP)

(72) Inventors: Takashi FUJIMOTO, Tokyo (JP); Koji TANAKA, Tokyo (JP); Reona FURUKAWA, Tokyo (JP); Kazuya KONISHI, Tokyo (JP); Shinya SONEDA, Tokyo (JP)

(73) Assignee: Mitsubishi Electric Corporation, Tokyo (JP)

(21) Appl. No.: 19/266,806

(22) Filed: Jul. 11, 2025

(30) Foreign Application Priority Data
Sep. 27, 2024 (JP) 2024-168248

(51) Int. Cl. H10D 12/00; H10D 62/10; H10D 62/60; H10D 64/27

(52) U.S. Cl. CPC H10D 12/481; H10D 62/103; H10D 62/60; H10D 64/516; H10D 64/518

(57) ABSTRACT

An object is to provide a technology that can suppress a decrease in the saturated current while reducing the amount of gate charge. A semiconductor device includes a semiconductor substrate with a drift layer, a carrier storage layer, and a base layer, and a two-stage active trench structure in the semiconductor substrate. A thickness of a lower-stage insulating film in contact with a side portion of a lower stage electrode is greater than a thickness of an upper-stage insulating film in contact with a side portion of an upper stage electrode, at least one of conditions (a), (b), or (c) is satisfied, and a lower end of the upper stage electrode is located above a position at which an integrated value of impurity concentrations of the carrier storage layer in a vertical direction is halved.

### BACKGROUND

### Technical Field

The present disclosure relates to a semiconductor device.

### Description of the Background Art

Proposed is a structure of a semiconductor device including an upper stage electrode and a lower stage electrode that are insulated from each other in a trench. In the structure, a lower-stage insulating film in contact with a side portion of the lower stage electrode is thicker than an upper-stage insulating film in contact with a side portion of the upper stage electrode (e.g., Japanese Patent No. 7061954). Such a structure can suppress a switching loss of the semiconductor device by a decrease in gate charge, while suppressing the influence of a channel to characteristics of a threshold voltage.

Thickening the lower-stage insulating film to reduce the amount of gate charge (Qg) in a two-stage active trench structure, however, results in a reduction in carrier concentration in a storage layer in a sidewall of a trench. This decreases a saturated current (Isat). Thus, the two-stage active trench structure has a problem in that the reduction in the amount of gate charge (Qg) cannot be compatible with sustaining the saturated current (Isat).

### SUMMARY

The present disclosure has been conceived in view of the problem, and has an object of providing a technology that can suppress a decrease in the saturated current while reducing the amount of gate charge.

A semiconductor device according to the present disclosure includes: a semiconductor substrate having a first main surface and including a drift layer of a first conductivity type, a carrier storage layer of the first conductivity type, and a base layer of a second conductivity type, the drift layer, the carrier storage layer, and the base layer being provided in this order toward the first main surface, the carrier storage layer being higher in impurity concentration than the drift layer; and at least one two-stage active trench structure disposed closer to the first main surface of the semiconductor substrate, the two-stage active trench structure including: a lower-stage insulating film provided in a lower portion of a trench, the trench penetrating the base layer and the carrier storage layer from the first main surface to reach the drift layer; a lower stage electrode provided on the lower-stage insulating film and electrically connected to a gate electrode; an upper-stage insulating film provided in an upper portion of the trench; and an upper stage electrode provided on the upper-stage insulating film, electrically connected to the gate electrode, and insulated from the lower stage electrode in the trench, wherein a thickness of the lower-stage insulating film in contact with a side portion of the lower stage electrode is greater than a thickness of the upper-stage insulating film in contact with a side portion of the upper stage electrode, at least one of conditions (a), (b), or (c) is satisfied, the condition (a) being a condition that a length of a portion of the upper stage electrode which protrudes downward from the base layer is less than a length of the lower stage electrode in a vertical direction, the condition (b) being a condition that a length of the upper stage electrode in the vertical direction is less than the length of the lower stage electrode in the vertical direction, the condition (c) being a condition that a cross-sectional area of the upper stage electrode in a cell region is smaller than a cross-sectional area of the lower stage electrode in the cell region, and a lower end of the upper stage electrode is located below a lower end of the base layer, and is located above a position at which an integrated value of impurity concentrations of the carrier storage layer in the vertical direction is halved.

The semiconductor device can suppress a decrease in the saturated current while reducing the amount of gate charge.

These and other objects, features, aspects, and advantages of the present disclosure will become more apparent from the following detailed description of the present disclosure when taken in conjunction with the accompanying drawings.

### BRIEF DESCRIPTION OF THE DRAWINGS

FIG. 1 is a top view illustrating a structure of a semiconductor device according to Embodiment 1;

FIG. 2 is a cross-sectional view illustrating a structure of the semiconductor device according to Embodiment 1;

FIG. 3 is a cross-sectional view illustrating a structure of the semiconductor device according to Embodiment 1;

FIG. 4 is a cross-sectional view illustrating a structure of the semiconductor device according to Embodiment 1;

FIG. 5 is a cross-sectional view illustrating a structure of the semiconductor device according to Embodiment 1;

FIG. 6 is a cross-sectional view illustrating a structure of a semiconductor device according to Modification 1;

FIG. 7 is a cross-sectional view illustrating a structure of a semiconductor device according to Modification 2;

FIG. 8 is a cross-sectional view illustrating a structure of a semiconductor device according to Modification 4;

FIG. 9 is a cross-sectional view illustrating a structure of a semiconductor device according to Modification 4;

FIG. 10 is a cross-sectional view illustrating a structure of a semiconductor device according to Modification 4;

FIG. 11 is a cross-sectional view illustrating a structure of a semiconductor device according to Embodiment 2;

FIG. 12 is a cross-sectional view illustrating a structure of a semiconductor device according to Embodiment 4;

FIG. 13 is a cross-sectional view illustrating a structure of a semiconductor device according to Embodiment 5; and

FIG. 14 is a cross-sectional view illustrating a structure of a semiconductor device according to Embodiment 6.

### DESCRIPTION OF THE PREFERRED EMBODIMENTS

Embodiments will be described with reference to the attached drawings. The features to be described in Embodiments below are mere exemplifications, and all of the features are not necessarily essential. In the description below, identical constituent elements in a plurality of Embodiments will be denoted by the same or similar reference numerals, and different constituent elements will be mainly described. In the following description, a particular position and a particular direction such as “up”, “down”, “left”, “right”, “front”, or “back” need not always coincide with an actual position and an actual direction. A portion higher in concentration than another portion may mean that, for example, an average of concentrations in the portion is higher than an average of concentrations in the other portion. Conversely, a portion lower in concentration than another portion may mean that, for example, an average of concentrations in the portion is lower than an average of concentrations in the other portion. Although the first conductivity type is described as n-type and the second conductivity type is described as p-type hereinafter, conversely, the first conductivity type may be p-type and the second conductivity type may be n-type.

### Embodiment 1

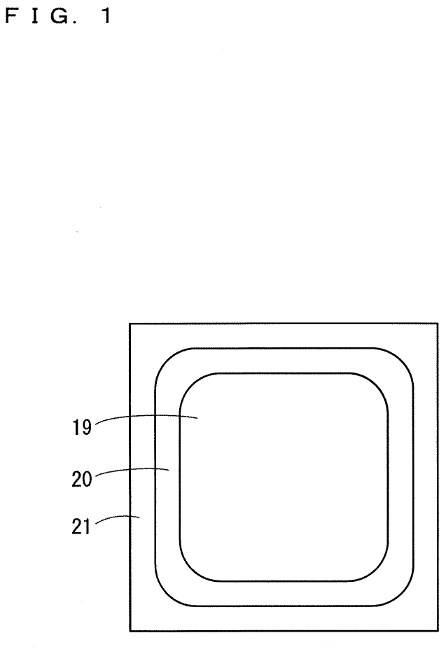

FIG. 1 is a top view illustrating a structure of a semiconductor substrate included in a semiconductor device according to Embodiment 1. In the semiconductor substrate in FIG. 1, a cell region 19 in which a semiconductor element is disposed, a termination region 20 surrounding the cell region 19, and a perimeter region 21 surrounding the termination region 20 are defined.

The semiconductor substrate may be made from a normal semiconductor wafer or an epitaxial growth layer. The semiconductor substrate may be made of normal silicon (Si), or a wide bandgap semiconductor such as silicon carbide (SiC), gallium nitride (GaN), gallium oxide (Ga₂O₃), or diamond. When the semiconductor substrate is made of a wide bandgap semiconductor, the semiconductor device can perform stable operations at high temperatures and high voltages, and accelerate the switching speed.

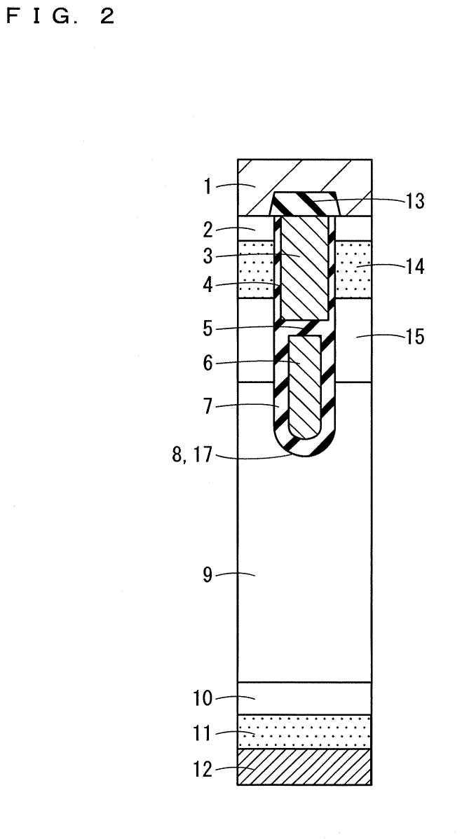

FIGS. 2 to 5 are cross-sectional views illustrating a structure of the semiconductor device according to Embodiment 1, specifically, cross-sectional views illustrating a structure of the cell region 19 in which the semiconductor element is disposed. Although a structure in which the semiconductor element is an insulated gate bipolar transistor (IGBT) will be described hereinafter, the structure is not limited to this. The semiconductor element may be, for example, a metal-oxide-semiconductor field-effect transistor (MOSFET) or a reverse conducting-IGBT (RC-IGBT) including an IGBT region with an IGBT and a diode region including, for example, a Schottky barrier diode (SBD) and a PN junction diode (PND).

As illustrated in FIG. 2, the semiconductor substrate includes an n⁻ type drift layer 9, an n-type carrier storage layer 15, a p-type base layer 14, an n⁺type source layer 2, an n-type buffer layer 10, and a p-type collector layer 11. The semiconductor substrate has a first main surface corresponding to an upper end of the source layer 2, and a second main surface corresponding to a lower end of the collector layer 11.

Next, the layers of the semiconductor substrate will be described. The carrier storage layer 15 higher in n-type impurity concentration than the drift layer 9 is provided closer to the first main surface with respect to the drift layer 9. The base layer 14 is provided closer to the first main surface with respect to the carrier storage layer 15. The source layer 2 higher in n-type impurity concentration than the carrier storage layer 15 is provided closer to the first main surface with respect to the base layer 14.

In the semiconductor substrate according to Embodiment 1, the drift layer 9, the carrier storage layer 15, the base layer 14, and the source layer 2 are provided in this order toward the first main surface. In the semiconductor substrate, the drift layer 9, the buffer layer 10, and the collector layer 11 are provided in this order toward the second main surface. Each of the layers of the semiconductor substrate is selectively formed by, for example, mask formation and ion implantation.

The semiconductor device includes not only the semiconductor substrate but also a two-stage active trench structure 17, an interlayer insulating film 13, and an emitter electrode 1, and a collector electrode 12.

The two-stage active trench structure 17 includes a lower-stage insulating film 7, a lower stage electrode 6, a boundary insulating film 5, an upper-stage insulating film 4, and an upper stage electrode 3, and is provided closer to the first main surface of the semiconductor substrate.

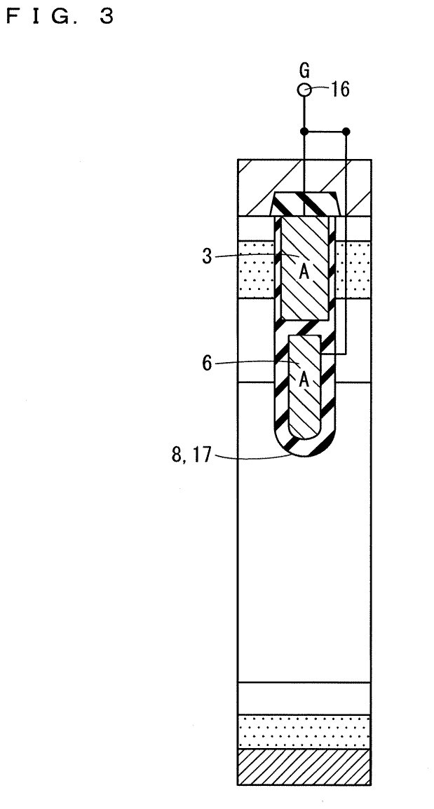

The lower-stage insulating film 7 is provided in a lower portion of a trench 8 that penetrates the source layer 2, the base layer 14, and the carrier storage layer 15 from the first main surface of the semiconductor substrate to reach the drift layer 9. The lower stage electrode 6 is provided on the lower-stage insulating film 7, and is electrically connected to a gate electrode 16 as illustrated in FIG. 3. Although not illustrated, the gate electrode 16 is provided in the semiconductor substrate similarly to the emitter electrode 1, and corresponds to a gate pad to which an external device applies a gate potential.

The boundary insulating film 5 in FIG. 2 is provided on an upper portion of the lower stage electrode 6. The upper-stage insulating film 4 is provided in an upper portion of the trench 8. The lower-stage insulating film 7, the boundary insulating film 5, and the upper-stage insulating film 4 are formed by, for example, thermal oxidation or chemical vapor deposition (CVD). The upper stage electrode 3 is provided on the upper-stage insulating film 4, and is insulated from the lower stage electrode 6 by the boundary insulating film 5 in the trench 8. A lower end of the upper stage electrode 3 is located below a lower end of the base layer 14. As illustrated in FIG. 3, the upper stage electrode 3 is electrically connected to the gate electrode 16.

The interlayer insulating film 13 in FIG. 2 is provided on the upper stage electrode 3. The emitter electrode 1 is provided to cover the source layer 2 and the interlayer insulating film 13, is electrically connected to the source layer 2, and is insulated from the upper stage electrode 3 by the interlayer insulating film 13. The collector electrode 12 is provided to cover the collector layer 11, and is electrically connected to the collector layer 11.

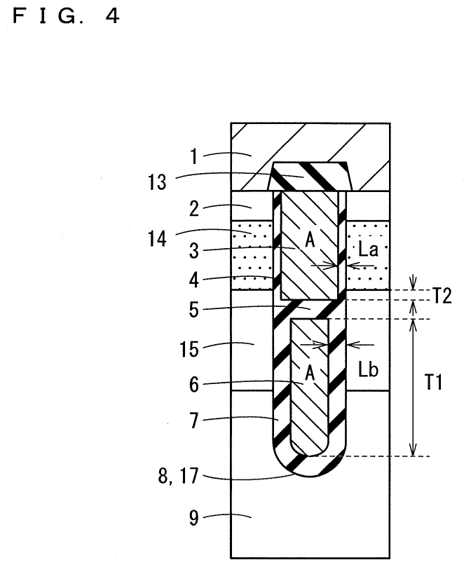

As illustrated in FIG. 4, a thickness (Lb) of the lower-stage insulating film 7 in contact with a side portion of the lower stage electrode 6 is greater than a thickness (La) of the upper-stage insulating film 4 in contact with a side portion of the upper stage electrode 3. Furthermore, a condition (a) that a length (T2) of a portion of the upper stage electrode 3 which protrudes downward from the base layer 14 is less than a length (T1) of the lower stage electrode 6 in the vertical direction is satisfied.

Here, the amount of gate charge (Qg) is proportional to a surface area of an insulating film, and is indirectly proportional to a thickness of the insulating film. Thus, the semiconductor device according to Embodiment 1 with the aforementioned structure can reduce the amount of gate charge (Qg) more than a structure in which a sum of the length (T1) and the length (T2) is equal to that of Embodiment 1 and the length (T2) is greater than the length (T1). In contrast, a carrier concentration in an n-type storage layer such as the carrier storage layer 15 in a sidewall of the trench 8 decreases in the semiconductor device with a greater thickness (Lb) of the lower-stage insulating film 7. Thus, carriers in an interface of the trench 8 decrease, and the saturated current (Isat) decreases.

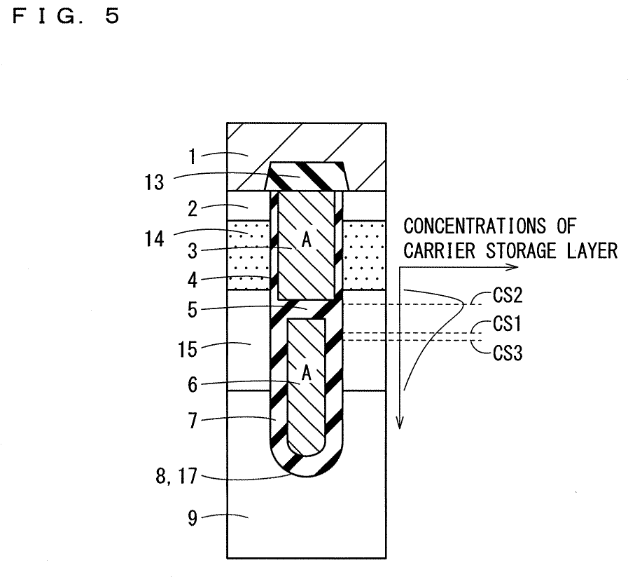

In Embodiment 1, the lower end of the upper stage electrode 3 is located above a position (CS1) at which an integrated value of impurity concentrations of the carrier storage layer 15 in the vertical direction is halved, as illustrated in FIG. 5. In general, the electric field in a boundary between the thinner upper-stage insulating film 4 and the thicker lower-stage insulating film 7 is increased in the two-stage active trench structure 17. Since the lower end of the upper stage electrode 3 is located above the position (CS1) in Embodiment 1, the boundary with the increased electric field is located closer to the base layer 14. This can increase the electric field of a mesa portion (i.e., a portion between the adjacent trenches 8) in the vicinity of a channel (i.e., the vicinity of the base layer 14), and reduce the field-plate effect of the trenches 8.

A current I injected from the channel is represented by I=qnμE, and is approximately proportional to the electric field E in the vicinity of the channel. Thus, an increase in the electric field in the vicinity of the channel increases a drift current. Thus, the semiconductor device according to Embodiment 1 can suppress a decrease in the saturated current (Isat) which occurs due to an increase in the thickness (Lb) of the lower-stage insulating film 7.

Preferably, a thickness of the lower-stage insulating film 7 in contact with not the side portion of the lower stage electrode 6 but a bottom thereof is greater than the thickness (La) of the upper-stage insulating film 4 in contact with the side portion of the upper stage electrode 3. Such a structure hardly allows the electric field to concentrate on the bottom of the two-stage active trench structure 17, and can proportionately increase the electric field of the mesa portion in the vicinity of the channel. Consequently, this can further suppress a decrease in the saturated current (Isat) which occurs due to an increase in the thickness (Lb) of the lower-stage insulating film 7.

### Summary of Embodiment 1

In the semiconductor device according to Embodiment 1, the thickness (Lb) of the lower-stage insulating film 7 in contact with the side portion of the lower stage electrode 6 is greater than the thickness (La) of the upper-stage insulating film 4 in contact with the side portion of the upper stage electrode 3, the length (T2) of the portion of the upper stage electrode 3 which protrudes downward from the base layer 14 is less than the length (T1) of the lower stage electrode 6 in the vertical direction, and the lower end of the upper stage electrode 3 is located above the position (CS1) at which the integrated value of impurity concentrations of the carrier storage layer 15 in the vertical direction is halved. Such a structure can suppress a decrease in the saturated current (Isat) while reducing the amount of gate charge (Qg).

### Modification 1

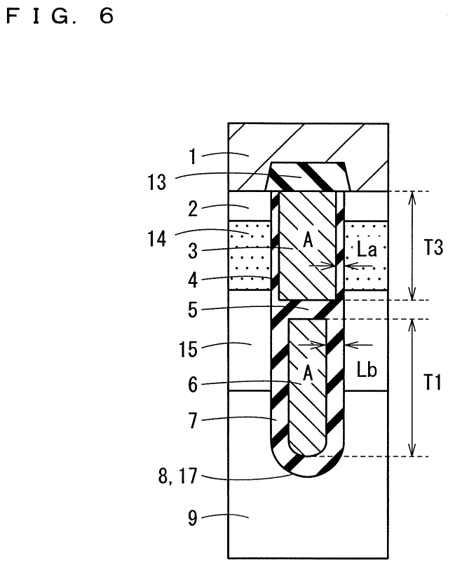

FIG. 6 is a cross-sectional view illustrating a structure of a semiconductor device according to Modification 1. In Embodiment 1, the condition (a) that the length (T2) of the portion of the upper stage electrode 3 which protrudes downward from the base layer 14 is less than the length (T1) of the lower stage electrode 6 in the vertical direction is satisfied. In Modification 1, not the condition (a) but a condition (b) that a length (T3) of the upper stage electrode 3 in the vertical direction is less than the length (T1) of the lower stage electrode 6 in the vertical direction is satisfied as illustrated in FIG. 6.

As described above, the amount of gate charge (Qg) is proportional to a surface area of an insulating film, and is indirectly proportional to a thickness of the insulating film. Thus, the semiconductor device according to Modification 1 with the aforementioned structure can reduce the amount of gate charge (Qg) more than a structure in which a sum of the length (T1) and the length (T3) is equal to that of Modification 1 and the length (T3) is greater than the length (T1). Since the structures according to Modification 1 except this are identical to those of Embodiment 1, the structures according to Modification 1 can suppress a decrease in the saturated current (Isat) while reducing the amount of gate charge (Qg).

### Modification 2

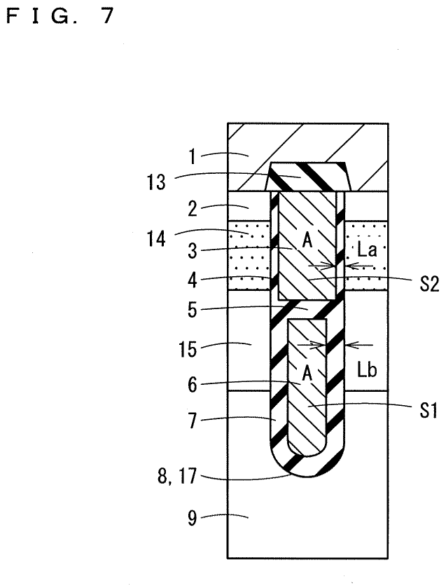

FIG. 7 is a cross-sectional view illustrating a structure of a semiconductor device according to Modification 2. In Modification 2, not the conditions (a) and (b) but a condition (c) that a cross-sectional area (S2) of the upper stage electrode 3 in the cell region 19 is smaller than a cross-sectional area (S1) of the lower stage electrode 6 in the cell region 19 is satisfied as illustrated in FIG. 7.

As described above, the amount of gate charge (Qg) is proportional to a surface area of an insulating film, and is indirectly proportional to a thickness of the insulating film. Thus, the semiconductor device according to Modification 2 with the aforementioned structure can reduce the amount of gate charge (Qg) more than a structure in which a sum of the cross-sectional area (S1) and the cross-sectional area (S2) is equal to that of Modification 2 and the cross-sectional area (S2) is larger than the cross-sectional area (S1). Since the structures according to Modification 2 except this are identical to those of Embodiment 1, the structures according to Modification 2 can suppress a decrease in the saturated current (Isat) while reducing the amount of gate charge (Qg).

In summary, at least one of the condition (a) according to Embodiment 1, the condition (b) according to Modification 1, or the condition (c) according to Modification 2 should be satisfied. In this specification, for example, at least one of A, B, C, . . . , or Z means any one of all combinations obtained by combining one type or more extracted from each of groups of A, B, C, . . . , and Z.

### Modification 3

In FIG. 5, a peak position (CS2) of the impurity concentrations of the carrier storage layer 15 is located above the position (CS1) at which the integrated value of the impurity concentrations of the carrier storage layer 15 in the vertical direction is halved. In such a case, the lower end of the upper stage electrode 3 may be located above the peak position (CS2). Since this structure can further increase the electric field of the mesa portion in the vicinity of the channel and further increase the drift current, a decrease in the saturated current (Isat) can further be suppressed.

In FIG. 5, a center position (CS3) of the carrier storage layer 15 in the vertical direction is located below the position (CS1) at which the integrated value of the impurity concentrations of the carrier storage layer 15 in the vertical direction is halved. Depending on the distribution of the impurity concentrations, however, the center position (CS3) may be located above the position (CS1). In such a case, the lower end of the upper stage electrode 3 may be located above the center position (CS3). Since this structure can further increase the electric field of the mesa portion in the vicinity of the channel and further increase the drift current, a decrease in the saturated current (Isat) can further be suppressed.

### Modification 4

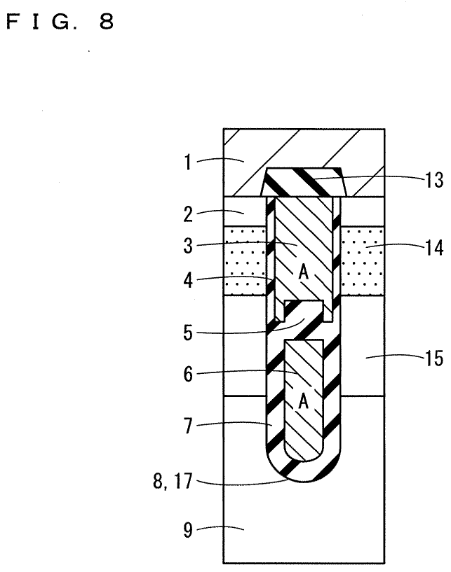

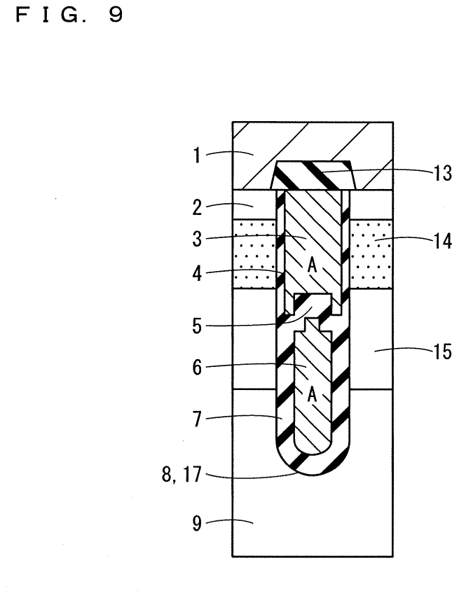

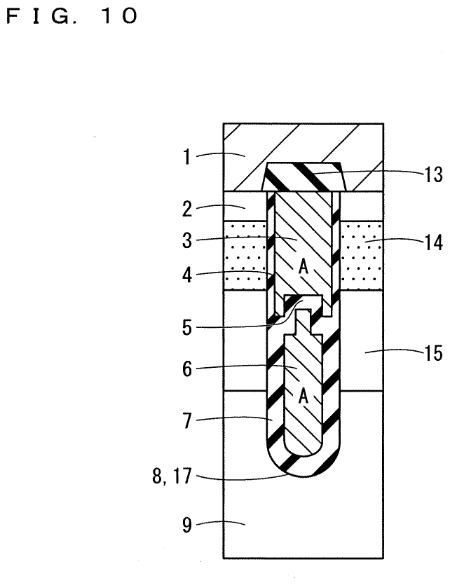

FIGS. 8 to 10 are cross-sectional views illustrating a structure of a semiconductor device according to Modification 4. As illustrated in FIG. 8, the bottom of the upper stage electrode 3 may have a depression that is bowed inward at the center. Furthermore, as illustrated in FIG. 9, the upper portion of the lower stage electrode 6 may have a protrusion protruding from the center. Furthermore, as illustrated in FIG. 10, the upper end of the lower stage electrode 6 may be located above the lower end of the upper stage electrode 3 in the structure of FIG. 9.

While Embodiment 2 and the following Embodiments will describe structures appropriately modified from the structure according to Embodiment 1, the modifications in Embodiment 2 and the following Embodiments may be applied to Modifications 1 to 4 above.

### Embodiment 2

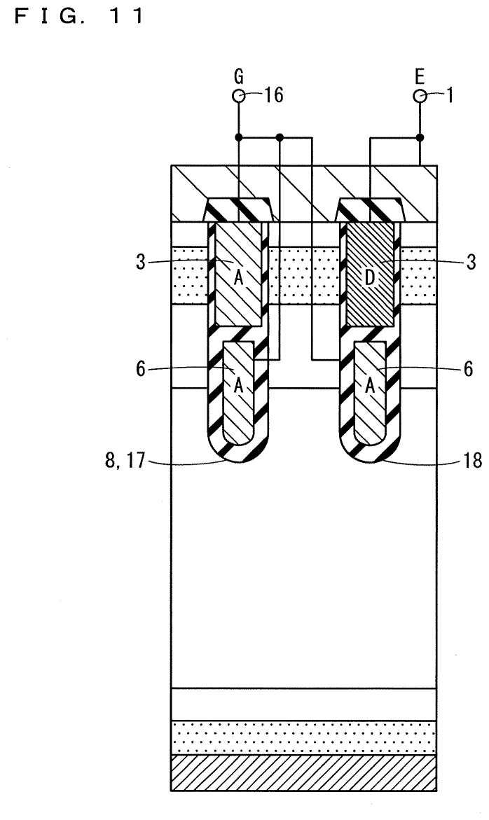

FIG. 11 is a cross-sectional view of a structure of a semiconductor device according to Embodiment 2. As illustrated in FIG. 11, not only the two-stage active trench structure 17 but also a dummy active trench structure 18 is disposed closer to the first main surface of the semiconductor substrate in Embodiment 2. The dummy active trench structure 18 is a structure corresponding to the two-stage active trench structure 17, that is, a structure similar to the two-stage active trench structure 17. In the dummy active trench structure 18, the upper stage electrode 3 is electrically connected to the emitter electrode 1 in place of the gate electrode 16.

In an upper stage portion of the dummy active trench structure 18 with such a structure, capacitance does not substantially occur. Thus, the semiconductor device according to Embodiment 2 can further reduce the amount of gate charge (Qg).

### Embodiment 3

In Embodiment 3, at least one of the conditions (a), (b), or (c) and Equation (1) below are satisfied.

A×Cgc1>(A+D)×Cgc2 (1)

“A” denotes the number of the two-stage active trench structures 17 in a cross-sectional view, whereas “D” denotes the number of the dummy active trench structures 18 in a cross-sectional view. “Cgc1” denotes the capacitance per unit length of the upper-stage insulating film 4 in contact with a side portion of a portion of the upper stage electrode 3 which protrudes downward from the base layer 14, and “Cgc2” denotes the capacitance per unit length of the lower-stage insulating film 7 in contact with the side portion of the lower stage electrode 6. Modifying Equation (1) produces Equation (2) below.

Y<100×(1−1/(Lb/La)) (2)

Y [%] denotes a ratio of the number of to the dummy active trench structures 18 to the number of to the two-stage active trench structures 17 and the dummy active trench structures 18 in a cross-sectional view, that is, a thinning ratio, and is represented by Y =100×D/(A+D). For example, when A=1 and A+D=N, Y is represented by Y=100×(N−1)/N. Similarly to Embodiment 1, “La” denotes the thickness of the upper-stage insulating film 4 in contact with the side portion of the upper stage electrode 3, whereas “Lb” denotes the thickness of the lower-stage insulating film 7 in contact with the side portion of the lower stage electrode 6.

Since at least one of the aforementioned conditions (a), (b), or (c) and Equation (2) (i.e., Equation (1)) are satisfied in Embodiment 3, the capacitance (Cgc) of the semiconductor device can be reduced. As a result, the amount of gate charge (Qg) can be reduced.

### Embodiment 4

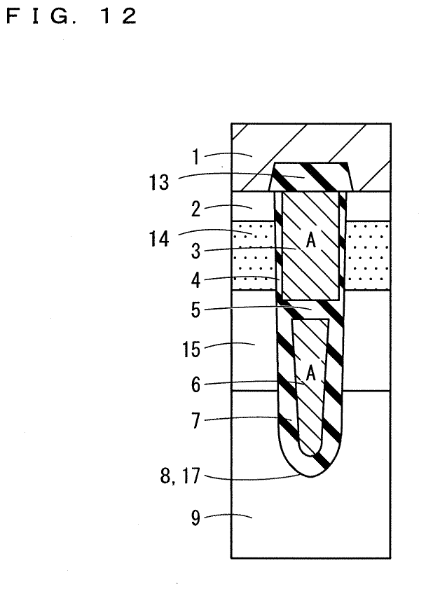

FIG. 12 is a cross-sectional view of a structure of a semiconductor device according to Embodiment 4. As illustrated in FIG. 12, the trench 8 has a tapered shape that is tapered toward the bottom in Embodiment 4.

A tapered angle of a sidewall of a tapered portion of the trench 8 with respect to the horizontal direction is preferably 89 degrees or less, more preferably 87 degrees or less, and much more preferably 85 degrees or less. Furthermore, the depth of the trench 8 is preferably 3 μm or more, more preferably 4 μm or more, and much more preferably 5 μm or more.

Since the semiconductor device according to Embodiment 4 can reduce the cross-sectional area of the lower-stage insulating film 7, the amount of gate charge (Qg) can further be reduced.

### Embodiment 5

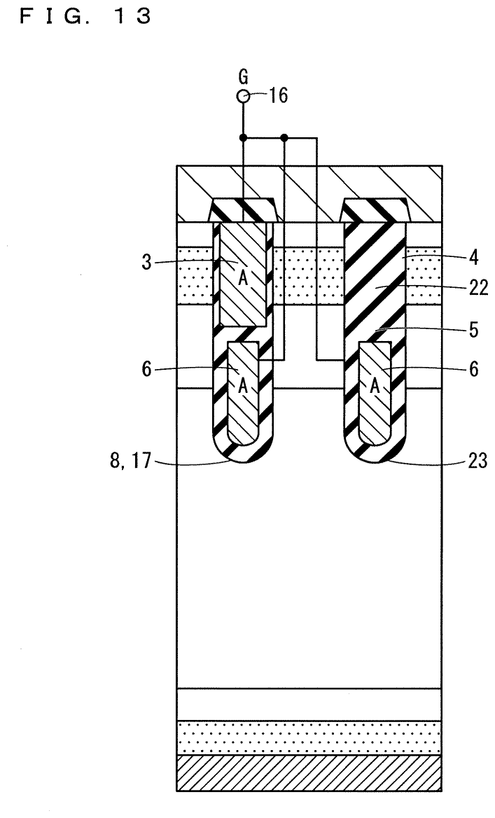

FIG. 13 is a cross-sectional view of a structure of a semiconductor device according to Embodiment 5. As illustrated in FIG. 13, not only the two-stage active trench structure 17 but also a recessed active trench structure 23 is disposed closer to the first main surface of the semiconductor substrate in Embodiment 5. The recessed active trench structure 23 is a structure corresponding to the two-stage active trench structure 17, that is, a structure similar to the two-stage active trench structure 17. The recessed active trench structure 23 contains an insulator 22 that is an insulating material in place of the upper stage electrode 3.

The insulator 22 may be a material identical to that of the upper-stage insulating film 4 or the interlayer insulating film 13. In a structure using the same material in these portions, the manufacturing steps can be simplified, and the manufacturing cost can be reduced.

The insulator 22 may be a thermal oxide film formed by thermal oxidation, or a CVD film formed by CVD. Since the thermal oxide film is superior in electrical characteristics to the CVD film, the gate characteristics can be improved when the insulator 22 is a thermal oxide film. In contrast, the CVD film is generally higher in impurity concentration than the thermal oxide film, and the manufacturing cost can be reduced. For example, the upper-stage insulating film 4 or the lower-stage insulating film 7 may be thermal oxide films superior in electrical characteristics, and the insulator 22 may be a CVD film. The insulator 22 may be higher in impurity concentration than the upper-stage insulating film 4 or the lower-stage insulating film 7.

In the dummy active trench structure 18 in FIG. 11 according to Embodiment 2, a capacitance (Cge) that is a factor responsible for increasing the amount of gate charge (Qg) occurs between the lower stage electrode 6 connected to the gate electrode 16 and the upper stage electrode 3 connected to the emitter electrode 1. Since the recessed active trench structure 23 according to Embodiment 5 can reduce the capacitance (Cge), the amount of gate charge (Qg) can further be reduced.

### Embodiment 6

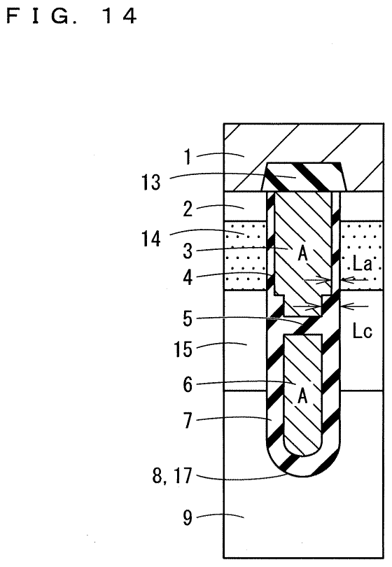

FIG. 14 is a cross-sectional view of a structure of a semiconductor device according to Embodiment 6. In Embodiment 6, the upper-stage insulating film 4 in contact with the side portion of the upper stage electrode 3 includes a first portion in contact with the base layer 14 and a second portion that is not in contact with the base layer 14 as illustrated in FIG. 14. A thickness (Lc) of the second portion is greater than a thickness (La) of the first portion. Since such a structure can reduce the capacitance of the second portion of the upper-stage insulating film 4, the amount of gate charge (Qg) can further be reduced.

In the present disclosure in English, “a” and “an” mean more than one. Thus, “a”, “an”, “one or more”, and “at least one”can be used for the same meaning.

Embodiments (modifications) can be freely combined, or appropriately modified and omitted.

A summary of various aspects of the present disclosure will be hereinafter described as Appendixes.

### Appendix 1

A semiconductor device, comprising:

a semiconductor substrate having a first main surface and including a drift layer of a first conductivity type, a carrier storage layer of the first conductivity type, and a base layer of a second conductivity type, the drift layer, the carrier storage layer, and the base layer being provided in this order toward the first main surface, the carrier storage layer being higher in impurity concentration than the drift layer; and

at least one two-stage active trench structure disposed closer to the first main surface of the semiconductor substrate,

the two-stage active trench structure including:
a lower-stage insulating film provided in a lower portion of a trench, the trench penetrating the base layer and the carrier storage layer from the first main surface to reach the drift layer;
a lower stage electrode provided on the lower-stage insulating film and electrically connected to a gate electrode;
an upper-stage insulating film provided in an upper portion of the trench; and
an upper stage electrode provided on the upper-stage insulating film, electrically connected to the gate electrode, and insulated from the lower stage electrode in the trench,

wherein a thickness of the lower-stage insulating film in contact with a side portion of the lower stage electrode is greater than a thickness of the upper-stage insulating film in contact with a side portion of the upper stage electrode,

at least one of conditions (a), (b), or (c) is satisfied, the condition (a) being a condition that a length of a portion of the upper stage electrode which protrudes downward from the base layer is less than a length of the lower stage electrode in a vertical direction, the condition (b) being a condition that a length of the upper stage electrode in the vertical direction is less than the length of the lower stage electrode in the vertical direction, the condition (c) being a condition that a cross-sectional area of the upper stage electrode in a cell region is smaller than a cross-sectional area of the lower stage electrode in the cell region, and

a lower end of the upper stage electrode is located below a lower end of the base layer, and is located above a position at which an integrated value of impurity concentrations of the carrier storage layer in the vertical direction is halved.

### Appendix 2

The semiconductor device according to appendix 1,

wherein the lower end of the upper stage electrode is located above a peak position of the impurity concentrations of the carrier storage layer.

### Appendix 3

The semiconductor device according to appendix 1,

wherein the lower end of the upper stage electrode is located above a center position of the carrier storage layer in the vertical direction.

### Appendix 4

The semiconductor device according to any one of appendixes 1 to 3, further comprising

at least one dummy active trench structure that is a structure corresponding to the two-stage active trench structure, the dummy active trench structure being electrically connected to an emitter electrode in place of the gate electrode.

### Appendix 5

The semiconductor device according to any one of appendixes 1 to 4,

wherein the trench has a tapered shape that is tapered toward a bottom of the trench.

### Appendix 6

The semiconductor device according to appendix 4,

wherein Y<100×(1−1/(Lb/La)) is satisfied, where Y [%] denotes a thinning ratio that is a ratio of the number of the at least one dummy active trench structure to the number of the at least one two-stage active trench structure and the at least one dummy active trench structure in a cross-sectional view, La denotes a thickness of the upper-stage insulating film, and Lb denotes a thickness of the lower-stage insulating film.

### Appendix 7

The semiconductor device according to any one of appendixes 1 to 6, further comprising

a recessed active trench structure that is a structure corresponding to the two-stage active trench structure, the recessed active trench structure containing an insulator in place of the upper stage electrode.

### Appendix 8

The semiconductor device according to any one of appendixes 1 to 7,

wherein the upper-stage insulating film in contact with the side portion of the upper stage electrode includes:

a first portion in contact with the base layer; and

a second portion that is not in contact with the base layer, the second portion being thicker than the first portion.

While the disclosure has been shown and described in detail, the foregoing description is in all aspects illustrative and not restrictive. It is therefore understood that numerous modifications and variations can be devised.

What is claimed is:

1. A semiconductor device, comprising:
a semiconductor substrate having a first main surface and including a drift layer of a first conductivity type, a carrier storage layer of the first conductivity type, and a base layer of a second conductivity type, the drift layer, the carrier storage layer, and the base layer being provided in this order toward the first main surface, the carrier storage layer being higher in impurity concentration than the drift layer; and
at least one two-stage active trench structure disposed closer to the first main surface of the semiconductor substrate,
the two-stage active trench structure including:
a lower-stage insulating film provided in a lower portion of a trench, the trench penetrating the base layer and the carrier storage layer from the first main surface to reach the drift layer;
a lower stage electrode provided on the lower-stage insulating film and electrically connected to a gate electrode;
an upper-stage insulating film provided in an upper portion of the trench; and
an upper stage electrode provided on the upper-stage insulating film, electrically connected to the gate electrode, and insulated from the lower stage electrode in the trench,
wherein a thickness of the lower-stage insulating film in contact with a side portion of the lower stage electrode is greater than a thickness of the upper-stage insulating film in contact with a side portion of the upper stage electrode,
at least one of conditions (a), (b), or (c) is satisfied, the condition (a) being a condition that a length of a portion of the upper stage electrode which protrudes downward from the base layer is less than a length of the lower stage electrode in a vertical direction, the condition (b) being a condition that a length of the upper stage electrode in the vertical direction is less than the length of the lower stage electrode in the vertical direction, the condition (c) being a condition that a cross-sectional area of the upper stage electrode in a cell region is smaller than a cross-sectional area of the lower stage electrode in the cell region, and
a lower end of the upper stage electrode is located below a lower end of the base layer, and is located above a position at which an integrated value of impurity concentrations of the carrier storage layer in the vertical direction is halved.

2. The semiconductor device according to claim 1,
wherein the lower end of the upper stage electrode is located above a peak position of the impurity concentrations of the carrier storage layer.

3. The semiconductor device according to claim 1,
wherein the lower end of the upper stage electrode is located above a center position of the carrier storage layer in the vertical direction.

4. The semiconductor device according to claim 1, further comprising
at least one dummy active trench structure that is a structure corresponding to the two-stage active trench structure, the dummy active trench structure being electrically connected to an emitter electrode in place of the gate electrode.

5. The semiconductor device according to claim 1,
wherein the trench has a tapered shape that is tapered toward a bottom of the trench.

6. The semiconductor device according to claim 4,
wherein Y<100×(1−1/(Lb/La)) is satisfied, where Y [%] denotes a thinning ratio that is a ratio of the number of the at least one dummy active trench structure to the number of the at least one two-stage active trench structure and the at least one dummy active trench structure in a cross-sectional view, La denotes a thickness of the upper-stage insulating film, and Lb denotes a thickness of the lower-stage insulating film.

7. The semiconductor device according to claim 1, further comprising
a recessed active trench structure that is a structure corresponding to the two-stage active trench structure, the recessed active trench structure containing an insulator in place of the upper stage electrode.

8. The semiconductor device according to claim 1,
wherein the upper-stage insulating film in contact with the side portion of the upper stage electrode includes:
a first portion in contact with the base layer; and
a second portion that is not in contact with the base layer, the second portion being thicker than the first portion.
